(19) United States
(12) Patent Application Publication
(10) Pub. No.: US 2025/0209225 A1
(43) Pub. Date: Jun. 26, 2025

(54) SYSTEM AND METHOD FOR INTENT-BASED COMPUTATIONAL SIMULATION IN A CONSTRUCTION ENVIRONMENT

(71) Applicant: Slate Technologies Inc., Pleasanton, CA (US)

(72) Inventor: Senthil Manickavasgam Kumar, Dublin, CA (US)

(21) Appl. No.: 18/847,868

(22) PCT Filed: Mar. 28, 2023
(86) PCT No.: PCT/US2023/016521

§ 371 Date: Sep. 17, 2024

Related U.S. Application Data
(60) Provisional application No. 63/324,715, filed on Mar. 29, 2022.

(30) Foreign Application Priority Data
Mar. 28, 2023 (WO) PCT/US2023/016521

(51) Int. Cl. G06F 30/13

(52) U.S. Cl. CPC G06F 30/13

(57) ABSTRACT

A method for generating a model recommendation in a computing environment is disclosed. The method comprises determining a user intent based on a user input for executing at least one intended task by the user, converting the determined user intent to one or more machine executable instructions, generating a plurality of scenarios based on the one or more machine executable instructions, evaluating an outcome of each of the plurality of scenarios by mapping it to one or more project objectives associated with the at least one intended task, and generating at least one model recommendation associated with the user intent based on the evaluation.

### RELATED APPLICATION(S)

This application claims priority to U.S. Provisional Patent Application having Ser. No. 63/324,715, filed Mar. 29, 2022, and titled “System and methods for intent-based factorization and computational simulation,” and U.S. patent application Ser. No. 17/894,418, filed Aug. 24, 2022, and titled “System and Method for Computational Simulation and Augmented/Virtual Reality in a Construction Environment,” the entire contents of which are hereby incorporated by reference for all purposes as if fully set forth herein.

### FIELD OF THE DISCLOSURE

The embodiments discussed in the present disclosure are generally related to artificial intelligence (AI) and machine learning (ML) in a construction environment. In particular, the embodiments discussed are related to the implementation of ML, AI, cognition, self-learning, and trainable systems and methods for intent-based factorization and computational simulation for optimal construction design in an Architecture, Engineering, and Construction (AEC) environment. The embodiments as discussed optimize the construction process all the way from Pre-Construction Planning and strategic endeavors to during construction tactical tasks, and predictive and proactive planning, and analysis to Post Construction Operational efficiencies.

### BACKGROUND OF THE DISCLOSURE

Appropriating an AEC environment for planning any construction related activity usually involves multiple processes and implementations including generation and management of diagrammatic and digital representations of a part or whole of construction designs, associated works, and several algorithms driven planning and management of human, equipment and material resources associated with undertaking the construction in a real-world environment. The process involves the creation of digital twins (e.g. a virtual representation) of a construction model, and simulation of various processes and events of a construction project. For example, these aspects may include a construction schedule, work packs, work orders, sequence and timing of materials needed, procurement schedule, timing and source for procurement, etc. Additional aspects including labor, duration, dependence on ecosystem factors, topology of the construction area, weather patterns, and surrounding traffic are also considered during aforesaid creation of the virtual representation. Furthermore, cost parameters, timelines, understanding and adherence to regulatory processes, and environmental factors, also play an important role in AEC planning. An AEC software represents a state of the algorithm driven approach to execute the AEC environment in any computer ranging from a latest invented to a general purpose computer. The AEC software spans the whole design concept-to-execution phase of construction projects and includes post-construction activities, for example, interior designing, furnishing, electric fixture installation, etc., as well. Such AEC software is used by organizations and individuals responsible for building, operating, and maintaining diverse physical infrastructures, from waterways to highways and ports, to houses, apartments, schools, shops, office spaces, factories, commercial buildings, and so on.

Largely for any construction related project, AEC software is equipped to be used for every step or stage of the project, from planning to designing virtually till actual construction as known to be realized through brick and mortar. A final output of the AEC software may be simulated logistics of the project and represented through a spreadsheet or a diagrammatic representation. By using the AEC software and accessing such final output, users can understand the relationships between buildings, building materials, and other systems in a variety of situations and attempt to account for them in their decision-making processes. However, current AEC software solutions are isolated frameworks and restricted to accepting inputs of certain types such as a standard rigid questionnaire. Accordingly, when confronted with a multitude and diverse input, the AEC solutions are unable to adapt or make decisions in real-time or near real-time to account for the dynamic nature of a construction project. In an example, parsing of a user query provided as a natural language input so as to drive the output of the AEC software requires an interfacing of the AEC with state of the art parsers such as language processors, thereby incurring time and expenditure to interface an external media with the AEC. Same rationale applies when it comes to attempting to drive the output of the ACE based on a user intent, which is not an explicit but an implicit input.

As explained before, conventional systems in the AEC field rely on manual and rule-based approaches (such as accepting only certain user inputs) for generating specific scenario-based outcomes. In an example, any Natural Language (NL) input provided by the user may not customize the output as intended and end up being ignored. Accordingly, these systems fail to comprehend dynamic variations in factors impacting construction and may fail to provide any meaningful insights or actionable guidance to improve the construction design.

This problem is exacerbated in the AEC field as factors that impact the construction schedule and design are many and varied. Some of these factors are near impractical to predict, plan, and accommodate until the factors come to pass or are likely to come to pass with some degree of certainty.

Accordingly, there is a need for technical solutions that address the needs described above, as well as other inefficiencies of the state of the art. Specifically, there lies a need to flag and harness a user intent while planning any project or activity. Further, there lies a need to intelligently infer user intent and automatically formulate optimal solution(s) for any project or activity. More specifically, there lies a need to automatically and intelligently extract a user intent from a given set of considerations and accordingly customize, adjust or fine tune further actions based on processing of said intent.

### SUMMARY OF THE DISCLOSURE

The following represents a summary of some embodiments of the present disclosure to provide a basic understanding of various aspects of the disclosed herein. This summary is not an extensive overview of the present disclosure. It is not intended to identify key or critical elements of the present disclosure or to delineate the scope of the present disclosure. Its sole purpose is to present some embodiments of the present disclosure in a simplified form as a prelude to the more detailed description that is presented below.

Embodiments of an AI-based system and a corresponding method are disclosed that address at least some of the above challenges and issues. In an embodiment, the subject matter of the present disclosure discloses a method for generating a model recommendation in a computing environment. The method comprises determining a user intent based on an input received from a user for executing at least one intended task by the user, converting the determined user intent to one or more machine executable instructions, generating a plurality of scenarios based on the one or more machine executable instructions, evaluating an outcome of each of the plurality of scenarios by mapping it to one or more project objectives associated with the at least one intended task, and generating at least one model recommendation associated with the user intent based on the evaluation.

In an embodiment of the present disclosure, the method may further include generating the plurality of scenarios by modifying one or more parameters associated with the at least one intended task, each modification associated with a corresponding optimized model.

In an embodiment of the present disclosure, the method further includes receiving the input from the user through a plurality of input streams, at least one of the plurality of input streams corresponding to a non-textual format, processing the plurality of input streams including converting the non-textual format of the at least one of the plurality of input streams to a textual format, generating one or more intent-based data sub-units by parsing and processing each of the plurality of input streams, generating machine executable instructions corresponding to the one or more intent-based data sub-units, and combining the generated machine executable instructions corresponding to each of the plurality of processed input streams to a combined machine executable instruction.

In an embodiment of the present disclosure, the method further includes generating one or more intent-based data sub-units by parsing and processing the received input, and converting the one or more intent-based data sub-units to machine executable instructions.

In an embodiment of the present disclosure, the method further includes receiving the input from the user as at least one of a text, image, video, gesture, and audio format.

In an embodiment of the present disclosure, the method further includes determining the user intent corresponding to a plurality of preferences of the user pertaining to execution of the at least one intended task.

In an embodiment of the present disclosure, the method further includes classifying the user intent as at least one of a temporal intent, a spatial intent, a fiscal intent, and a societal intent.

In an embodiment of the present disclosure, the method further includes evaluating the outcome of each of the plurality of scenarios, the evaluating comprises generating a set of constraints based on the one or more project objectives, mapping the outcome of each of the plurality of scenarios to the set of constraints, and shortlisting one or more of the plurality of scenarios based on the mapping.

In an embodiment of the present disclosure, the method further includes providing the at least one model recommendation to the user through a visual display, and enabling the user to execute a modification in real-time through an interface to the at least one model recommendation.

In an embodiment, the subject matter of the present disclosure discloses a system for generating a model recommendation in a computing environment, said system comprising a controller configured to: determine a user intent based on an input received from a user for executing at least one intended task by the user, convert the determined user intent to one or more machine executable instructions, generate a plurality of scenarios based on the one or more machine executable instructions, evaluate an outcome of each of the plurality of scenarios by mapping it to one or more project objectives associated with the at least one intended task, and generate at least one model recommendation associated with the user intent based on the evaluation.

In an embodiment of the present disclosure, the controller is further configured to generate the plurality of scenarios by modifying one or more parameters associated with the at least one intended task, each modification associated with a corresponding optimized model.

In an embodiment of the present disclosure, the controller is further configured to receive the user input through a plurality of input streams, at least one of the plurality of input streams corresponding to a non-textual format, process the plurality of input streams including converting the non-textual format of the at least one of the plurality of input streams to a textual format, generate one or more intent-based data sub-units by parsing and processing each of the plurality of input streams, generate machine executable instructions corresponding to the one or more intent-based data sub-units, and combine the generated machine executable instructions corresponding to each of the plurality of processed input streams to a combined machine executable instruction.

In an embodiment of the present disclosure, the controller is further configured to generate one or more intent-based data sub-units by parsing and processing the received input, and convert the one or more intent-based data sub-units to machine executable instructions.

In an embodiment of the present disclosure, the controller is further configured to receive the input from the user through a plurality of input streams, at least one of the plurality of input streams corresponding to a non-textual format, process the plurality of input streams including converting the non-textual format of the at least one of the plurality of input streams to a textual format, generate one or more intent-based data sub-units by parsing and processing each of the plurality of input streams, generate machine executable instructions corresponding to the one or more intent-based data sub-units, and combine the generated machine executable instructions corresponding to each of the plurality of processed input streams to a combined machine executable instruction.

In an embodiment of the present disclosure, the input from the user is in at least one of a text, image, video, gesture, and audio format.

In an embodiment of the present disclosure, wherein the determined user intent is classifiable as at least one of a temporal intent, a spatial intent, a fiscal intent, and a societal intent.

In an embodiment of the present disclosure, the controller is further configured to generate a set of constraints based on the one or more project objectives, and map the outcome of each of the plurality of scenarios to the set of constraints, and shortlist one or more of the plurality of scenarios based on the mapping.

In an embodiment of the present disclosure, the controller is further configured to provide the at least one model recommendation to the user through a visual display and enable the user to execute a modification in real-time through an interface to the at least one model recommendation.

In an embodiment, the subject matter of the present disclosure may relate to non-transitory computer-readable storage medium, having stored thereon a computer-executable program which, when executed by at least one processor, causes the at least one processor to determine a user intent based on an input received from a user for executing at least one intended task by the user, convert the determined user intent to one or more machine executable instructions, generate a plurality of scenarios based on the one or more machine executable instructions, evaluate an outcome of each of the plurality of scenarios by mapping it to one or more project objectives associated with the at least one intended task, and generate at least one model recommendation associated with the user intent based on the evaluation.

In an embodiment of the present disclosure, the computer-executable program further causes the at least one processor to receive the user input through a plurality of input streams, at least one of the plurality of input streams corresponding to a non-textual format, process the plurality of input streams including converting the non-textual format of the at least one of the plurality of input streams to a textual format, generate one or more intent-based data sub-units by parsing and processing each of the plurality of input streams, generate machine executable instructions corresponding to the one or more intent-based data sub-units, and combine the generated machine executable instructions corresponding to each of the plurality of processed input streams to a combined machine executable instruction.

In an embodiment of the present disclosure, the computer-executable program further causes the at least one processor to provide the at least one model recommendation to the user through a visual display and enable the user to execute a modification in real-time through an interface to the at least one model recommendation.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will be appreciated that the scope of the disclosure encompasses many potential embodiments in addition to those here summarized, some of which will be further described below.

### BRIEF DESCRIPTION OF DRAWINGS

Further advantages of the disclosure will become apparent by reference to the detailed description of preferred embodiments when considered in conjunction with the drawings. In the drawings, identical numbers refer to the same or a similar element.

FIG. 1 illustrates an example networked computer system, in accordance with the embodiments presented herein.

FIG. 2A illustrates a flowchart for a method for intent-based factorization and computational simulation, in accordance with the embodiments presented herein.

FIG. 2B illustrates an example simulation of a to-be-constructed building as a virtual or augmented reality, in accordance with an embodiment of the present disclosure.

FIG. 3 illustrates a sequential flow diagram for intent-based factorization and computational simulation, in accordance with the embodiments presented herein.

FIG. 4 is a schematic diagram illustrating processing of multiple input streams, in accordance with the embodiments presented herein.

FIG. 5 illustrates a sequential flow diagram for generating a model recommendation, in accordance with the embodiments presented herein.

FIG. 6 illustrates a sequential flow diagram for generating a model recommendation based on an acoustic user input, in accordance with the embodiments presented herein.

### DETAILED DESCRIPTION

The following detailed description is presented to enable a person skilled in the art to make and use the disclosure. For purposes of explanation, specific details are set forth to provide a thorough understanding of the present disclosure. However, it will be apparent to one skilled in the art that these specific details are not required to practice the disclosure. Descriptions of specific applications are provided only as representative examples. Various modifications to the preferred embodiments will be readily apparent to one skilled in the art, and the general principles defined herein may be applied to other embodiments and applications without departing from the scope of the disclosure. The present disclosure is not intended to be limited to the embodiments shown but is to be accorded the widest possible scope consistent with the principles and features disclosed herein.

Certain terms and phrases have been used throughout the disclosure and will have the following meanings in the context of the ongoing disclosure.

The Architecture, Engineering, and Construction (AEC) environment is an industry segment that utilizes a set of tools such as Building Information Modeling (BIM) and computer aided design (CAD) to support construction projects all the way from design till actual construction stage.

A “network” may refer to a series of nodes or network elements that are interconnected via communication paths. In an example, the network may include any number of software and/or hardware elements coupled to each other to establish the communication paths and route data/traffic via the established communication paths. In accordance with the embodiments of the present disclosure, the network may include, but is not limited to, the Internet, a local area network (LAN), a wide area network (WAN), an Internet of things (IoT) network, and/or a wireless network. Further, in accordance with the embodiments of the present disclosure, the network may comprise, but is not limited to, copper transmission cables, optical transmission fibers, wireless transmission, routers, firewalls, switches, gateway computers, and/or edge servers.

A “device” may refer to an apparatus using electrical, mechanical, thermal, etc., power and having several parts, each with a definite function and together performing a particular task. In accordance with the embodiments of the present disclosure, a device may include, but is not limited to, one or more IOT devices. Further, one or more IOT devices may be related, but are not limited to, connected appliances, smart home security systems, autonomous farming equipment, wearable health monitors, smart factory equipment, wireless inventory trackers, ultra-high speed wireless internet, biometric cybersecurity scanners, and shipping container and logistics tracking.

“Virtual Reality (VR)” is a computer-generated environment with scenes and objects that appear to be real. This environment as may be generated as a virtually constructed building or any 3D establishment is perceived through a device known as a Virtual Reality headset or helmet.

“Augmented reality” is an interactive experience of a real-world environment where the objects that reside in the real world are enhanced by computer-generated perceptual information, sometimes across multiple sensory modalities, including visual, auditory, haptic, somatosensory and olfactory. For example, a real world snap of plinth beam of an under construction building may be annotated in a color code different from cantilever beam owing to different physical characteristics.

“Feature vector” is a vector containing multiple elements about an object. Putting feature vectors for objects together can make up a feature space. The granularity depends on what someone is trying to learn or represent about the object. In an example, a 3 dimensional feature may be enough for simulating a passage in a building as compared to a plinth beam which may require 5 dimensional features for being more sensitive structural component of a building.

The term “device” in some embodiments, may be referred to as equipment or machine without departing from the scope of the ongoing description.

A “processor” may include a module that performs the methods described in accordance with the embodiments of the present disclosure. The module of the processor may be programmed into the integrated circuits of the processor, or loaded in memory, storage device, or network, or combinations thereof.

“Machine learning” may refer to as a study of computer algorithms that may improve automatically through experience and by the use of data. Machine learning algorithms build a model based at least on sample data, known as “training data,” in order to make predictions or decisions without being explicitly programmed to do so. Machine learning algorithms are used in a wide variety of applications, such as in medicine, email filtering, speech recognition, and computer vision, where it is difficult or unfeasible to develop conventional algorithms to perform the needed tasks.

In machine learning, a common task is the study and construction of algorithms that can learn from and make predictions on data. Such algorithms function by making data-driven predictions or decisions, through building a mathematical model from input data. These input data used to build the model are usually divided in multiple data sets. In particular, three data sets are commonly used in various stages of the creation of the model: training, validation, and test sets. The model is initially fit on a “training data set,” which is a set of examples used to fit the parameters of the model. The model is trained on the training data set using a supervised learning method. The model is run with the training data set and produces a result, which is then compared with a target, for each input vector in the training data set. Based at least on the result of the comparison and the specific learning algorithm being used, the parameters of the model are adjusted. The model fitting can include both variable selection and parameter estimation.

Successively, the fitted model is used to predict the responses for the observations in a second data set called the “validation data set.” The validation data set provides an unbiased evaluation of a model fit on the training data set while tuning the model's hyperparameters. Finally, the “test data set” is a data set used to provide an unbiased evaluation of a final model fit on the training data set.

“Deep learning” may refer to a family of machine learning models composed of multiple layers of neural networks, having high expressive power and providing state-of-the-art accuracy.

“Database” may refer to an organized collection of structured information, or data, typically stored electronically in a computer system.

“Data feed” is a mechanism for users to receive updated data from data sources. It is commonly used by real-time applications in point-to-point settings as well as on the World Wide Web.

“Ensemble learning” is the process by which multiple models, such as classifiers or experts, are strategically generated and combined to solve a particular computational intelligence problem. Ensemble learning is primarily used to improve the (classification, prediction, function approximation, etc.) performance of a model, or reduce the likelihood of an unfortunate selection of a poor one. In an example, an ML model selected for gathering a user intent from an input is different from an ML model required for processing a statistical input for sensitivity.

In accordance with the embodiments of the disclosure, a system for determining a user intent in a computing environment is described. The system comprises a controller configured to determine an intent of a user from an input received from the user for executing at least one intended task by the user and generate a feature set based on analyzing the intent of the user and extract a plurality of features from the determined intent. The system comprises a model ensemble configured to process at least one data feed received from a knowledge database based on the determined intent of the user to select at least one plan of action for executing the at least one intended task. Further, the system comprises a notifier configured to simulate the at least one plan of action as virtual or augmented reality based on the feature set to enable at least one of responding an additionally received input from the user and perform the at least one intended task according to the determined user intent.

In an embodiment, the input is received from the user as at least one of a text, image, video, gesture, and audio format and the determined intent of the user corresponds to a plurality of preferences of the user pertaining to execution of the at least one intended task. In an embodiment, the determined intent of the user is classifiable as at least one of a temporal intent, a spatial intent, a fiscal intent, and a societal intent. In an embodiment, the feature set corresponds to a multi-dimensional design vector comprising at least one of: a position coordinate system, cost, sustainability, safety, facility management, a construction principle, and an industry standard.

In an embodiment, the model ensemble for processing the data feed is configured to process one or more data feeds by an ensemble learning unit based on the determined intent. In an embodiment, the controller is further configured to provide recommendations of a plurality of activities to be implemented according to the determined intent for performance of the at least one intended task. In an embodiment, the notifier is configured to simulate the plan of action for the at least one intended task in accordance with at least one objective related to the at least one intended task, wherein the at least one objective is determined from the input based on a natural language parser and a work tokenizer and the notifier configured to simulate the plan of action is configured to simulate a plurality of constructional requirements of a project as the augmented reality. The augmented reality comprises an actual image of a site augmented by at least one content item representing the plurality of construction requirements associated with at least one portion of the actual image.

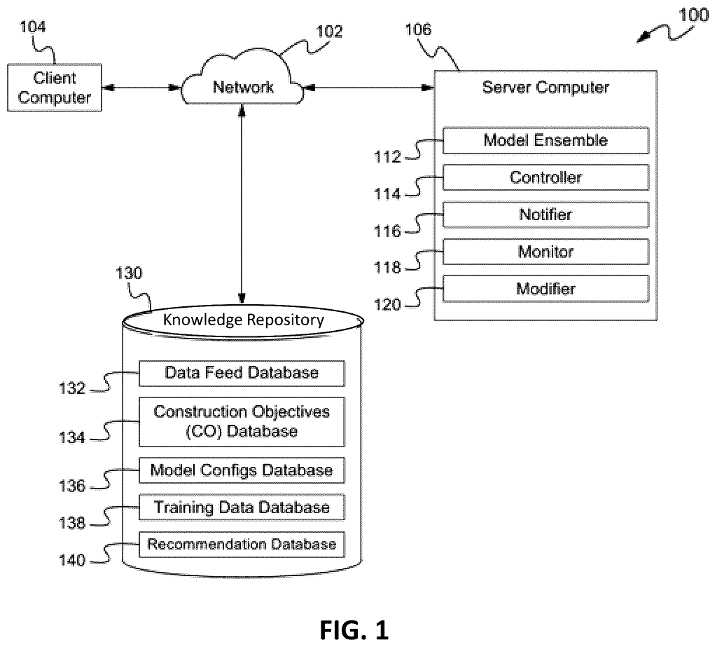

The embodiments of the methods and systems are described in more detail with reference to FIGS. 1-6.

FIG. 1 illustrates an example networked computer system 100 with which various embodiments of the present disclosure may be implemented. FIG. 1 is shown in simplified, schematic format for purposes of illustrating a clear example and other embodiments may include more, fewer, or different elements. FIG. 1 and the other drawing figures, and all of the description and claims in this disclosure are intended to present, disclose and claim a technical system and technical methods. The technical system and methods as disclosed includes specially programmed computers, using a special-purpose distributed computer system design and instructions that are programmed to execute the functions that are described. These elements execute to provide a practical application of computing technology to the problem of optimizing schedule, resource allocation, and work sequencing for AEC planning and execution. In this manner, the current disclosure presents a technical solution to a technical problem, and any interpretation of the disclosure or claims to cover any judicial exception to patent eligibility, such as an abstract idea, mental process, method of organizing human activity or mathematical algorithm, has no support in this disclosure and is erroneous.

In some embodiments, the networked computer system 100 may include a client computer 104, a server computer 106, and a knowledge repository 130, which are communicatively coupled directly or indirectly via a network(s) 102. In an embodiment, the server computer 106 broadly represents one or more computers, such as one or more desktop computers, server computers, a server farm, a cloud computing platform, a parallel computer, virtual computing instances in public or private datacenters, and/or instances of a server-based application. The server computer 106 may be accessible over the network 102 by the client computer 104 to request a schedule or a resource recommendation. The client computer 104 may include a desktop computer, laptop computer, tablet computer, smartphone, or any other type of computing device that allows access to the server computer 106. The elements in FIG. 1 are intended to represent one workable embodiment but are not intended to constrain or limit the number of elements that could be used in other embodiments.

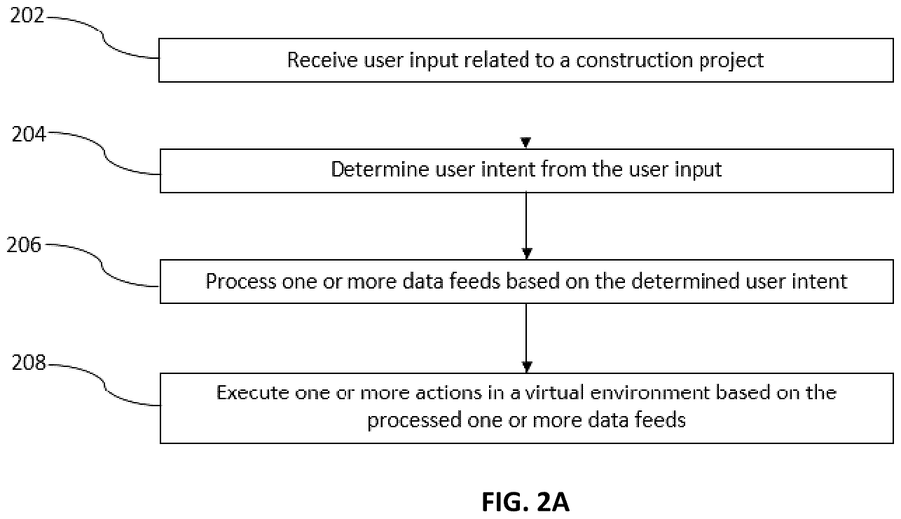

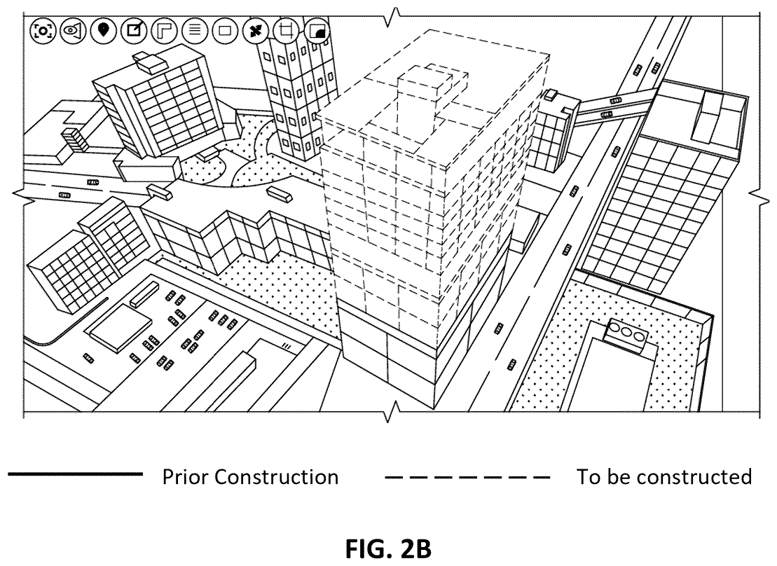

The server computer 106 may include one or more computer programs or sequences of program instructions in organization. Such organization implements artificial intelligence/machine learning algorithms to generate data pertaining to various requirements, such as design consideration factors in a construction project, controlling functions, notifying functions, monitoring functions, and modifying functions. A set of diverse or even mutually exclusive programs or sequences of instructions are organized together to implement diverse functions to generate data associated with design consideration factors. Such set may be referred to herein as a model ensemble 112 to implement an ensemble learning. Programs or sequences of instructions organized to implement the controlling functions (as later elaborated in forthcoming description of FIG. 1 and in FIG. 2) may be referred to herein as a construction schedule supervisor controller 114 (referred to as “controller 114” herein). Programs or sequences of instructions organized to implement the notifying functions (as later elaborated in forthcoming description of FIG. 1 and in FIG. 2) may be referred to herein as a notifier 116. Programs or sequences of instructions organized to implement the monitoring functions (as later elaborated in FIG. 2) may be referred to herein as an efficiency analysis and process monitor 118 (referred to as “monitor 118” herein). Programs or sequences of instructions organized to implement the modifying functions (as later elaborated in forthcoming description of FIG. 1 and in FIG. 2) may be referred to herein as a modifier 120. The controller 114, the notifier 116, the monitor 118 and the modifier 120 may be integrated together as a system on chip or as separate processors/controllers/registers. Accordingly, as may be clear from the forthcoming description of FIG. 1 and the description of FIG. 2, the respective functions of the controller 114, the notifier 116, the monitor 118, and the modifier 120 essentially correspond to processing or controller functions.

The model ensemble 112, the controller 114, the notifier 116, the monitor 118, and/or the modifier 120 may be part of an artificial intelligence (AI) system implemented by the server computer 106. In an embodiment, the networked computer system 100 may be an AI system and may include the client computer 104, the server computer 106, and the knowledge repository 130 that are communicatively coupled to each other. In an embodiment, one or more components of the server computer 106 may include a processor configured to execute instructions stored in a non-transitory computer readable medium.

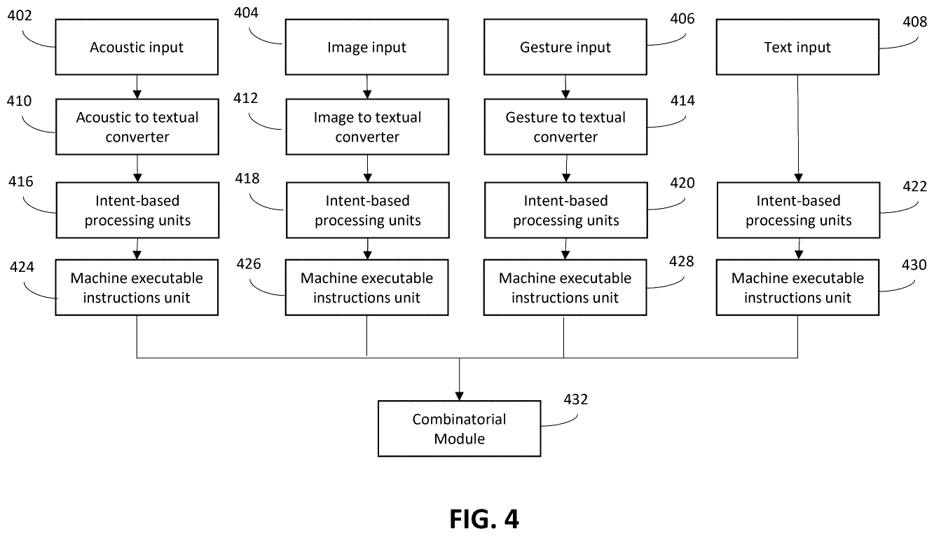

In an embodiment, the controller 114 is programmed to receive a user input, for example, via an interface such as a graphic user interface or a sensor such as an acoustic sensor, imaging sensor etc. The user input may be in the form of a single media input and/or a multimedia input. For example, the user may provide an image as an input and may also enter a textual content related to the image. Thus, data from both input streams, that is, the image and the text are considered as the user input by the controller 114. The controller 114 further processes and parses user input from multiple input streams, as will be described in detail with reference to FIG. 4. Accordingly, the controller 114 determines, from the user input, an intent of a user towards fulfilling one or more construction objectives associated with a construction project such as building or bridge construction. In an example, the intent corresponds to a contextual interpretation arising from the user input and does not correspond to a literal meaning emanating from the user input. The objective on the other hand may correspond to an ulterior motive behind provision associated with the user input and again not apparent from the user input. Example intent and objectives have been further elaborated in steps of FIG. 2A.

In an embodiment, the model ensemble 112 may include a plurality of modules, and each of the plurality of modules may include an ensemble of one or more machine learning models (e.g. Multilayer Perceptron, Support Vector Machines, Bayesian learning, K-Nearest Neighbor) to process a corresponding data feed. The data feed in turn corresponds to current data received in real-time from data sources such as a local or remote database as corresponding to the knowledge database 132. Each module, which is a combination of plurality of ML modules, is programmed to receive a corresponding data feed from the knowledge database 132. Based on pertinent segments or attributes of the data feed mapping with a function objective(s), a respective module determines or shortlists an intermediary data set that includes consideration factors in a construction project. The data feed is defined by a data structure comprising a header and that includes metadata or tags at an initial section or a header of the data feed, such that the metadata or tags identify segments and corresponding data types. Alternatively, in absence of header, the metadata or tags may be mixed with payload in the data feed. For example, each data segment of the data feed may include metadata indicating a data type that the data segment pertains to. If the data type corresponds with the function objective of the respective module, then the respective module will process that data segment. The intermediary data sets may then be used by the controller 114 to execute one or more actions based on user inputs, as described in more detail later.

For example, a Micro-Climate Analysis Module would only process those segments of a data feed that are relevant to the function objectives of the Micro-Climate Analysis Module (e.g., weather analysis, prediction, determination, recommendation, etc.). Put differently, the Micro-Climate Analysis Module identifies and processes those segments that have metadata indicating a weather data type. If a data feed includes only weather data, then the Micro-Climate Analysis Module would process the entire data feed. If a data feed does not include any weather data, then that data feed is not processed by the Micro-Climate Analysis Module.

In an embodiment, the notifier 116 may be programmed to provide notifications to the user. The notifier 116 may receive such notifications from the controller 114 and the knowledge repository 130. The notifications may include, but not limited to, audio, visual, or textual notifications in the form of indications or prompts. The notifications may be indicated in a user interface (e.g., a graphical user interface) to the user. In one example, the notifications may include, but not limited to, one or more recommended actions to fulfill the construction objectives based on an intent of the user. In other example, a notification indicates digital simulation of a real-world appearance of a construction site as a virtual environment (e.g. a metaverse of an under-construction building). In other example, a notification indicates a superimposition/overlay of the virtual environment on a real-time visual data feed of the construction site (e.g. a virtual view of a constructed bare ceiling superimposed by virtual wooden beams). In other example, a notification allows an avatar or personified animation of the user to navigate the virtual environment for visual introspection through a virtual reality headgear worn over the head and/or a stylus pen held in hand as known in the state of the art. Based on a head or limb movement of the user wearing the virtual reality headgear, the avatar may walk-through or drive-through various virtual locations of the metaverse. In other example, a notification facilitates such avatar to make real-time changes/updates/annotations that affect upcoming construction of the construction project. In other example, the notification facilitates the avatar's interaction with avatars of other users in a collaborative virtual environment. In other example, a notification indicates a transition between a virtual view and a real-world view of the construction site. In other example, a notification indicates construction details such as cost information and/or construction materials used.

In an embodiment, the monitor 118 is programmed to receive feedback that may be used to execute corrections and alterations at the controller 114 side to fine tune decision making. Example feedback may be manually provided by the user via an input interface (e.g., graphical user interface) about issues and problems such as construction status, delays, etc., or may be automatically determined by the monitor 118. In an example, the current status regarding the construction may be compared by the monitor with an earlier devised proposal to detect deviations and thereby detect the issues and problems. For such purposes, the monitor 118 is also programmed to receive data feeds from one or more external sources, such as on-site sensors or videos, and to store the data feeds in the knowledge repository 130.

In some embodiments, the modifier 120 is programmed to receive modification data to update existing artificial intelligence models in the system 100 and to add new artificial intelligence models to the system 100. Modification data may be provided as input by the user via an input interface (e.g., a graphical user interface). In other example, the modification may be sensed automatically through state of the art sensors such as an acoustic or imaging sensor.

In some embodiments, in keeping with sound software engineering principles of modularity and separation of function, the model ensemble 112, the controller 114, the notifier 116, the monitor 118, and the modifier 120 are each implemented as a logically separate program, process, or library. They may also be implemented as hardware modules or a combination of both hardware and software modules without limitation.

Computer executable instructions described herein may be in machine executable code in the instruction set of a CPU and may be compiled based upon source code written in Python, JAVA, C, C++, OBJECTIVE-C, or any other human-readable programming language or environment, alone or in combination with scripts in JAVASCRIPT, other scripting languages and other programming source text. In another embodiment, the programmed instructions may also represent one or more files or projects of source code that are digitally stored in a mass storage device such as non-volatile RAM or disk storage, in the systems of FIG. 1 or a separate repository system, which when compiled or interpreted cause generation of executable instructions that in turn upon execution cause the computer to perform the functions or operations that are described herein with reference to those instructions. In other words, the figure may represent the manner in which programmers or software developers organize and arrange source code for later compilation into an executable, or interpretation into bytecode or the equivalent, for execution by the server computer 106.

The server computer 106 may be communicatively coupled to the knowledge repository 130 that includes a knowledge database 132, a construction objectives (CO) database 134, a model configuration database 136, a training data database 138, and a recommendation database 140.

In some embodiments, the knowledge database 132 may store a plurality of data feeds collected from various sources such as a construction site or an AEC site, third-party paid or commercial databases, and real-time feeds, such as RSS, or the like. A data feed may include data segments pertaining to real-time climate and forecasted weather data, structural analysis data, in-progress and post-construction data, such as modular analysis of quality data, inventory utilization and forecast data, regulatory data, global event impact data, supply chain analysis data, equipment & Internet of Things (IoT) metric analysis data, labor/efficiency data, and/or other data that are provided to the modules of the model ensemble 112 in line with respective construction objective(s). A data feed may include tenant data relating to either other ancillary construction projects or activities of such ancillary construction projects, or both. Each data segment may include metadata indicating a data type of that data segment. As described herein, the real-time data, near real-time data, and collated data are received by the monitor 118 and are processed by various components of the server computer 106 depending on the user intent and construction objectives.

In some embodiments, the CO database 134 includes a plurality of construction objectives. Each of the plurality of data feeds in the knowledge database 132 is processed to achieve one or more construction objectives of the plurality of construction objectives in the CO database 134. The construction objectives, as exemplified in forthcoming description, are a collection of different user requirements, project requirements, regulatory requirements, technical requirements, or the like. Construction objectives may be established prior to start of construction activities and can be adjusted during construction phases to factor in varying conditions. Construction objectives are defined at each construction project and construction phase level. Data definition of construction objectives defines normalized construction objectives. Examples of such normalized objectives include parameters for optimization of construction schedule to meet time objectives, optimization for cost objectives, optimization for Carbon footprint objectives, which are normalized to factor in worker health, minimize onsite workers, and minimize quality issues. One or more construction objectives may be identified as part of a schedule request for a construction activity of a construction project. Further, the objective may be determined from the user input and/or the intent based on a natural language parser and a work tokenizer.

In one example, a construction objective may be to keep the cost below a budgeted amount. The monitor 118 may receive data feeds corresponding to cost analysis from external sources and store the data feeds in knowledge database 132. The controller 114 may receive the data feeds from the knowledge database 132 or, alternatively, receive the data feeds from the monitor 118. The controller 114 may then check the received data feeds against the established objectives (e.g. a set benchmark or threshold) to be in alignment for set construction objectives. For example, if the incoming data feeds indicate that construction completion date may exceed deadline, then the controller 114 explores one or more solutions to expedite. In this context, the controller 114 may determine that reshuffling of tasks, adding additional construction workers and procuring materials from a nearby supplier even at the cost of higher expenditure than proposed budget is expected to minimize shipping time and eventually help in meeting the proposed deadline associated with the completion date. However, since the desired objective is also to keep the cost below or at the allotted budget level, system recommendation from the controller 114 might also resort to overlook expediency and instead maintain work at the current pace with the current mandates. Such system recommendation to ignore expediency and persist with the current pace and resources is expected to have checked the CO database 134 as well as any other legal commitments, before giving up the options to expedite and persist with current pace. In a different exemplary scenario, if the construction objective may be to honor the set construction completion date at the cost of preset budget, then the system recommendation may override the current pace of work and instead enforce its explored recommendations to expedite, e.g., adding additional construction workers, procuring material from a nearby supplier among other considerations.

In an embodiment, the model configuration database 136 may include configuration data, such as parameters, gradients, weights, biases, and/or other properties, that are required to run the artificial intelligence models after the artificial intelligence models are trained.

In an embodiment, the training data database 138 may include training data for training one or more artificial intelligence models of the system 100. The training data database 138 is continuously updated with additional training data obtained within the system 100 and/or external sources. Training data includes historic customer data and synthetically algorithm-generated data tailored to test efficiencies of the different artificial intelligence models described herein. Synthetic data may be authored to test a number of system efficiency coefficients. This may include false positive and negative recommendation rates, model resiliency, and model recommendation accuracy metrics. An example of training data set may include data relating to task completion by a contractor earlier than a projected time schedule. Another example of training data set may include data relating to quality issues on the work completed by the contractor on the same task. Another example of a training data set may include several queries on construction projects received over a period of time from multiple users as user inputs. Yet another example of a training data set may include a mapping between queries and associated user intent for each query. The controller 114 may refer to this mapping while determining a new query from a user on an associated construction project.

In some embodiments, the recommendation database 140 includes recommendation data, such as recommended actions to optimize schedules to complete a construction project. Schedule optimization includes a shortest path for meeting the construction objective(s), selective work packages to include, supplier recommendation (based on proximity, quality and cost) and contractor recommendation. An example construction schedule includes all tasks ordered by priority, grouped tasks known as work packages, and resources assigned to the tasks. As discussed herein, schedule optimization is dynamic in nature as it relies and adjudicates based upon the current schedule progression, anticipated impedance, and impact due to quality issues and supply constraints.

The knowledge repository 130 may include additional databases storing data that may be used by the server computer 106. Each database 132, 134, 136, 138, and 140 may be implemented using memory, e.g., RAM, EEPROM, flash memory, hard disk drives, optical disc drives, solid state memory, or any type of memory suitable for database storage.

The network 102 broadly represents a combination of one or more local area networks (LANs), wide area networks (WANs), metropolitan area networks (MANs), global interconnected internetworks, such as the public internet, or a combination thereof. Each such network may use or execute stored programs that implement internetworking protocols according to standards such as the Open Systems Interconnect (OSI) multi-layer networking model, including but not limited to Transmission Control Protocol (TCP) or User Datagram Protocol (UDP), Internet Protocol (IP), Hypertext Transfer Protocol (HTTP), and so forth. All computers described herein may be configured to connect to the network 102 and the disclosure presumes that all elements of FIG. 1 are communicatively coupled via the network 102. The various elements depicted in FIG. 1 may also communicate with each other via direct communication links that are not depicted in FIG. 1 to simplify the explanation.

The ML models disclosed herein may include appropriate classifiers and ML methodologies. Some of the ML algorithms include (1) Multilayer Perceptron, Support Vector Machines, Bayesian learning, K-Nearest Neighbor, or Naive Bayes as part of supervised learning, (2) Generative Adversarial Networks as part of Semi Supervised learning, (3) Unsupervised learning utilizing Autoencoders, Gaussian Mixture and K-means clustering, and (4) Reinforcement learning (e.g., using a 0-learning algorithm, using temporal difference learning), and other suitable learning styles. Knowledge transfer is applied, and, for small footprint devices, Binarization and Quantization of models is performed for resource optimization for ML models. Each module of the plurality of ML models can implement one or more of: a regression algorithm (e.g., ordinary least squares, logistic regression, stepwise regression, multivariate adaptive regression splines, locally estimated scatterplot smoothing, etc.), an instance-based method (e.g., k-nearest neighbor, learning vector quantization, self-organizing map, etc.), a regularization method (e.g., ridge regression, least absolute shrinkage and selection operator, elastic net, etc.), a decision tree learning method (e.g., classification and regression tree, iterative dichotomiser 3, C4.5, chi-squared automatic interaction detection, multivariate adaptive regression splines, gradient boosting machines, etc.), a Bayesian method (e.g., naïve Bayes, averaged one-dependence estimators, Bayesian belief network, etc.), a kernel method (e.g., a support vector machine, a radial basis function, a linear discriminate analysis, etc.), a clustering method (e.g., k-means clustering, expectation maximization, etc.), an associated rule learning algorithm (e.g., an Eclat algorithm, etc.), an artificial neural network model (e.g., a Perceptron method, a back-propagation method, a self-organizing map method, a learning vector quantization method, etc.), a deep learning algorithm (e.g., a restricted Boltzmann machine, a deep belief network method, a convolution network method, a stacked auto-encoder method, etc.), and a dimensionality reduction method (e.g., principal component analysis, partial least squares regression, multidimensional scaling, etc.). Each processing portion of the system 100 can additionally leverage: a probabilistic, heuristic, deterministic or other suitable methodologies for computational guidance, recommendations, machine learning or combination thereof. However, any suitable machine learning approach can otherwise be incorporated in the system 100. Further, any suitable model (e.g., machine learning, non-machine learning, etc.) can be used in the system 100 of the present disclosure.

FIG. 2A illustrates a flowchart for a method for intent-based factorization and computational simulation, in accordance with the embodiments presented herein. FIG. 2B illustrates an example simulation of a to-be-constructed building as a virtual or augmented reality, in accordance with an embodiment of the present disclosure. FIG. 2A and FIG. 2B will be explained in conjunction with the description of FIG. 1.

In FIG. 2A, in step 202, the server computer 106 may receive a user input from a user via the client computer 104 in relation to an intended task or a project to be executed. For instance, a user may provide the user input in a text, image, video, or audio format to the client computer 104. The client computer 104 may transmit the received user input to the server computer 106 via the network 102.

In one example, the user input may include a query, an instruction, and/or an electronic file related to the construction project acting as the task to be performed. For instance, one user input may be a query regarding the progress of a construction project, materials used for the construction project, a location of the project, a projected timeline of completion, and/or any changes in construction activity to expedite the completion of the construction project. Another user input may be an instruction to create a virtual representation of a construction project based on a construction blueprint provided by the user. The blueprint may include artefacts such as, but not limited to, a Computer Aided Design (CAD) documentation, a 2-dimensional (2D) floor plan, and/or a 3-dimensional (3D) architecture layout to construct a 3D digital/virtual representation (e.g. metaverse) of the construction project based on a Building Information Model (BIM). In another embodiment, the user input may include an instruction to create the virtual representation of the construction project based on an intent of the user, without any specific artefact provided by the user. For instance, the user may provide a verbal input as “create a 5-story building with minimal environmental impact” or “show cost-effective ways to install wooden beams on the roof of 1st floor”. Accordingly, the user input is parsed for example through a natural language (NL) parser to determine keywords and thereby determine intent and objective as further detailed in step 204.

Yet another user input may be an instruction to superimpose a real-time data feed (real-world view) of a construction project on a virtual representation of the construction project. For example, as shown in FIG. 2B, a computer aided drawing (CAD) diagram of a 5-story building (as shown in dashed lines) may be superimposed by real-time data over an already constructed first floor (shown in solid lines) and amidst already existing habitation such as preexisting surrounding building, parking lot, flyover, roads, etc, which are also shown in solid lines in FIG. 2B. In other example, the CAD diagram of the entire building (if yet to be constructed) may be instantiated or superimposed by the real-time data over an actual image or simulation of a locality, zone, land parcel or plot to visualize the construction. The representation of FIG. 2B may be a virtual reality wherein all the entities are animated or an augmented reality, wherein merely the to-be-constructed building or building floors are animated and remaining representation may be a real-life photograph of site comprising the habitation. Further, another user input may be an instruction to facilitate navigation of an avatar of the user in the virtual environment (may also include the superimposed real-time view). In one example, the user input may include an instruction to facilitate a virtual walk-through or drive-through of a live construction site such as the simulated 5th floor of the building as shown in FIG. 2B. Inside the example simulated floor, a bare ceiling is superimposed by real-time view of wood beams being constructed. Yet another user input may be to an instruction to facilitate the avatar to make visual modifications or annotations on the virtual representation of any portion of the construction project. Another user input may be an instruction to activate interaction of the avatar with avatars of other users in a multi-user collaborative environment (e.g. the avatar of the user may interact with the avatar of the project manager on future course of action of the construction project).

In an embodiment, the functions of the server computer 106 may be personified into a virtual AI assistant as an Avatar. In one example, the avatar may be named as ‘ADAM’. In this embodiment, the avatar of the user may interact with Adam to provide all above-described user inputs. Adam may respond to the user with suitable responses and/or actions in response to the user inputs based on the following steps. For example, user wearing the virtual reality headgear moves his head up. Accordingly, Adam in the virtual reality environment also bends his head upwards so that a roof of the building may be seen to the user. In case the user now bends his hand carrying a stylus pen, Adam may actually annotate or scribble a note for the part of the roof as comment to be followed up. Other gadgets such as joystick or even bare hand movement is also conceivable as a part of navigation and annotation. For enabling Adam to actually walk through the virtual reality environment, for example to enter one room from another, the user wearing the headgear may execute a slight leg movement in a particular direction.

In step 204, the controller 114 may determine an intent of the user based on processing the user input as provided for the performance of the task which may be the construction project. In case the user input is a single media content such as voice or text based which in turn corresponds to Natural Language (NL), then the parsing may be performed based on Natural Language Processing (NLP) Algorithms, such as, but not limited to, Keyword Extraction, Knowledge Graphs, and Tokenization. In other examples, if the user input is image-based then the parsing may be performed based on machine learning techniques and deep learning models, such as, but not limited to, Convolutional Neural Networks (CNNs) and Recurrent Neural Networks (RNNs). For example, convolutional neural networks consist of several layers with small neuron collections, each of them perceiving small parts of an image. The results from all the collections in a layer partially overlap in a way to create the entire image representation. In yet another example, irrespective of the type of input as provided which may be single media or multimedia based, a parser of the user input parser may be a Machine Learning (ML) enabled parser that intuitively and predictively executes the parsing process. In yet another example, non-ML enabled parser may be employed that may be based on linear regression, Markov Model etc. Determination of the user intent based on processing of the user input from a single or multiple input streams is further discussed below with reference to FIG. 4.

Further, as a part of present step 204, the intent as determined may be computed as a feature set or feature vector for processing by either the aforementioned or a separate machine learning (ML) model. Specifically, the intent of the user implies preferences of the user to incorporate factors (or in other words features) that may impact the physical construction of a project. In one example, these factors may be based on a multi-dimensional design model e.g. (a 10-dimensional design model) that takes into consideration a plurality of factors (e.g., 10 factors, etc.) such as, but not limited to, X, Y, and Z coordinates of position coordinate system, cost, sustainability, safety, facility management, lean construction principles, and industry standards for constructions. In an example, the plurality of factors are territorial and location specific such that factors may be depended upon topography, topography, terrain, climate, etc., of a particular area. In other example, the facts also vary due to non-environmental factors such as resource availability, traffic conditions, demography, supply-chain influencing a particular area or locality. In yet another example, the extent of factors may be high (e.g. a 15 dimensional model) for a densely populated city such as New York as compared to sparsely populated area such as Louisville which may manage with a 5 or 6 dimensional model. The embodiments presented herein enable these factors to be considered during the virtual construction of the construction project before initiating the physical construction, which makes the construction process more efficient compared to conventional AEC mechanisms. For instance, a user intent may include incorporating safety principles. The virtual construction may accordingly include earthquake resistant mechanisms or fire-resistant mechanisms in the virtual representation of the construction project. If a user intent includes lean construction principles, the virtual representation may include usage of raw materials that require minimum wastage.

In one example, the intent of the user may include one or more of a temporal intent (e.g. intent related to timelines associated with the construction project), a spatial intent (e.g., intent related to location of the construction project), a fiscal intent (intent related to financial aspects of the construction project), and a societal intent (intent related to societal or environmental factors).

In an embodiment, the controller 114 may implement a combination of AI/ML algorithms along with natural language processing (NLP) and natural language understanding (NLU) to understand the intent of the user from the user input. For example, if the user input includes a statement “Are we on schedule on this project?”, the controller 114 may interpret that the user is interested in knowing the timeline of the completion (temporal intent). In another example, user's input may include a statement “Construct a 10-story building with minimum delay and expenses”. The controller 114 may interpret this as temporal and fiscal intent of the user for the specified construction. For example, the “minimum delay” and “minimum expenses” as keywords are extracted and classified under the genre “temporal” and “fiscal” by the NL parser and/or a word tokenizer as a part of intent extraction and analysis. In other example, generator adversarial or discriminator based ML network may be appended to the NL parser to precisely find the genre or label as “temporal” or “fiscal”. Likewise, using the similar concepts and/or analogous technologies, if the user's input includes an instruction “Let's minimize wastage while constructing this building”, the controller 114 may interpret this as a societal intent to minimize wastage and reduce environmental impact. Likewise, in other scenario, wherein the user input gesture based or a code-word based, state of the art decryption and gesture recognition based algorithms may be employed to decipher the intent underlying the user input.

In step 206, the model ensemble 112 defining an ensemble learning may process one or more data feeds received from the knowledge database 132 based on the user intent determined by the controller 114. In one example, if the user intent is to save cost of raw materials used for construction, the model ensemble 112 may automatically process data feed related to real-time cost quotes of several raw-material suppliers and accordingly, evaluate the suppliers to select the most relevant suppliers for the construction project. For instance, in a Just-In-Time (JIT) inventory related scenario, the model ensemble 114 may access from the knowledge database 132, real-time inventory data, supplier information, and cost quotes of global suppliers to present an inventory proposal to the user.

In another example, if the user's intent is to annotate objects or mark-ups on the virtual representation of 5-story under-construction building, the model ensemble 112 may process the live-feed from cameras installed in the under-construction building to superimpose a completed portion (e.g. first floor) on the virtual representation of the entire 5-story building.

In step 208, the controller 114 selects at-least one plan of action for executing the at least one task based on processing the data feed and thereby executes one or more selected plan of actions in the virtual environment based on the processed data feeds. A plurality of actions forming a part of the plan of action may include a response to additional user's inputs or performing the at least one intended task according to the user intent to fulfill the construction objectives or the one or more objectives associated with the task to be performed. The actions may be simulated as virtual or augmented reality based on the feature set (as related to the intent) as a response to the user input from the user. The simulation may also be directed to cause performance of an operation in furtherance of the user intent as determined in preceding steps.

In one example, the actions may include, providing recommendations on construction activities that is implemented according to the user intent and to fulfill the construction objectives. The recommendations pertain to a plurality of activities to be implemented according to the user intent for performance of the task. The actions may alternately or additionally, include a default construction plan for a construction object in order to enable the virtual representation at meeting the construction objectives. The actions may alternately or additionally, include rendering a virtual environment as a virtual reality that includes the virtual representation of the construction project, a virtual navigation (e.g. walk-through, drive-through, or a drone-view) in the virtual representation for visual introspection. For example, an under construction building may be simulated such that Adam personifying the user can virtually walk from one room to another based on gestures, head, limb movements executed by the user wearing the virtual reality headgear. At a particular position in the virtual environment, a head raise executed by the user in real life leads Adam to also look skywards in the virtual environment and see the roof of the building under construction therein. In another example as a part of augmented reality, a superimposition of real-time data of the construction project may be performed over the virtual representation to display a real-time progress of the construction project. The augmented reality may comprise an actual image of a site augmented by at least one content item (a graphical object, text or audio) representing any construction requirements or any information associated with one or more portions of the actual image. In example of virtual reality, user-annotated markups on the virtual representation of the construction project may be shown as a part of the simulation.

Largely, the simulation either as virtual reality or augmented reality corresponds to simulation of the plan of action for the at least one task in accordance with at least one objective related to the at least one task. In an example, the simulation of the plan of action includes simulation of a plurality of constructional requirements of a project as the augmented reality. In other example, the simulation through virtual or augmented reality supports multi contour terrain navigation with an ability to swap terrain. Further, a backdrop of augmented reality may be based on drone or vehicle-based inspection and exhibits a traversal and visual introspection. In an example of augmented reality, the topography may be simulated against the backdrop of real world features. Furthermore, augmented reality may support injection of real-world scenarios to simulate an impact in real-time upon actual physical attributes and physical needs of a building. As part of both augmented and virtual reality, multiple users may be teleported into the digital world in “Avatar” form for multi-user real-time simulations. In other example, on the lines of state of the art artificial intelligence (AI) assistants such as “Alexa”, “Siri”, a personified AI assistant in the form of bot applications may be provided to modify or auto correct the user inputs provided in real-time. Such bot application may work in tandem or independently with respect to the above mentioned Adam based application.

These actions may be triggered by the user inputs described in step 202. In an embodiment where the user input is provided to the personified virtual AI assistant, the virtual AI assistant may execute some or all the above-described actions in the virtual environment. Alternately or additionally, some or all these actions may be executed without the virtual AI assistant and the corresponding notifications may be displayed via a graphical user interface to the user.

In an embodiment, the construction of the virtual representation of the construction project incorporates real-world simulation of factors that could impede the construction schedule and/or optimal completion of the physical building. In one example, the model ensemble 112 may determine the potential impact of physical environmental factors such as direction of rain, velocity of wind, impact of heat, and probability of floods on the construction project and accordingly, construct the virtual representation. For instance, the controller 114 may modify the attributes of walls, windows, or pillars of the virtual representation to incorporate real-world constructional requirements. In another example, the controller 114 may recommend actions to reduce fuel wastage in heavy machinery used for the construction project.

The embodiments presented herein further enable machine learning of construction trends over a period of time and implement the learning to customize the actions to a specific user's preferences/intent. Therefore, the user may experience an optimal construction solution before the physical construction is initiated. Based on a prior construction data or historical data, factors that influence construction over a period of time or various instants of time are obtained. In an example, such factors include construction schedule dependencies and indicate as to what sets of actions may be done together or independently to optimize a schedule associated with achieving various outcomes such as wall finishing, surface treatment, curing, synthetic application of paints. Alongside, timelines for achieving outcomes may be predicted i.e. a duration of time for achieving each of the outcome. Furthermore, resources needed, human effort involved for achieving each of the outcomes may be predicted. Additionally, the outcomes sharing common traits may be grouped or clustered based on aforesaid historical data and a prior empirical data. The aforesaid factors, predicted timelines, etc., may be augmented with additional predictions such as information about weather, type of material (to be used or not used). From prior learnings, training data set, and application of a trained machine learning network such as a neural network, a prefabricated unit or artefact may be recommended for usage that is fabricated offsite and merely assembled on site, thereby doing away with a manufacturing overhead onsite.

In view of the above description, the embodiments presented herein enable the carrying of session-based identity information along with its security posture and the identity's application access credentials, from the source device to the destination device during the session. The embodiments presented herein also enable a data-plane function that performs a continuous vetting (verification) of the identity over the application access session and implement necessary action when the vetting fails. In the conventional network security mechanism, a solution that enables the above aspects, does not exist.

In view of the above description, the embodiments presented herein may be leveraged to render geospatial overlays in the realm of Geographic information system (GIS) that superimpose different type of data sets together and thereby creates a composite map by combining the geometry and attributes of different data sets. In an example, the geospatial overlays or GIS overlays are dependent upon environmental factors such as topography, topography, terrain, climate, etc., of particular area and also due to non-environmental factors such as resource availability, traffic conditions, demography, supply-chain influencing a particular area or locality. In an example, the subject matter of present disclosure when applied to render the geospatial overlay can be used to find an optimum location to construct a new school, hospital, police station, industrial corridors etc. Such optimum location may be found for example based on environmental factors such as a climatic condition or topography, such as flat area for school building. Non-environmental factors or commercial attributes influencing the optimum location selection may include nearness to recreation sites, and far from existing schools, etc.

Other example application of the present embodiment with respect to overlays include providing material overlay (e.g. for flooring), smart building overlays in construction industry, cost overlays, and temporal overlays in natural language processing. As may be understood, smart building overlays may in turn be based on a plurality of factors such as lighting, temperature optimization, material optimization.

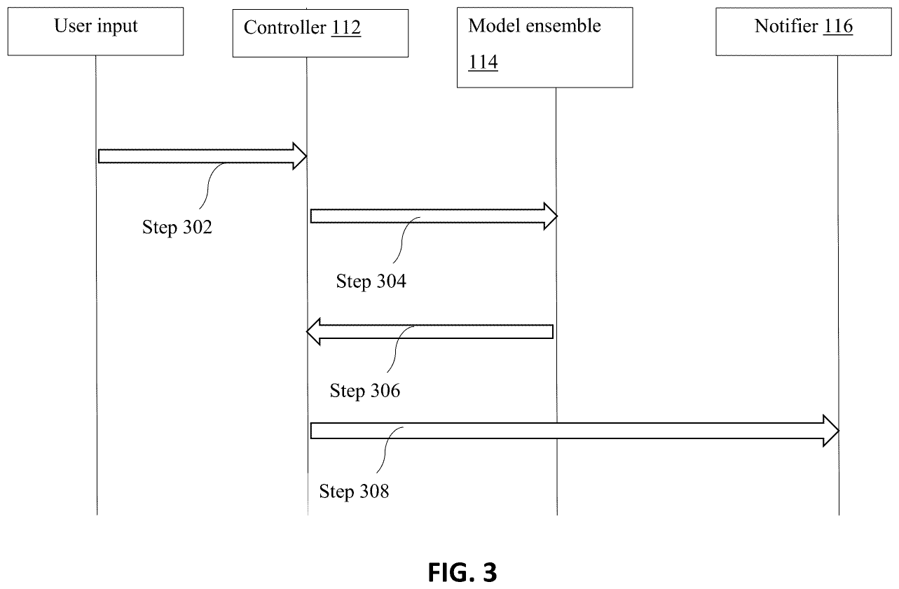

FIG. 3 illustrates a method for simulating scenarios and generating model recommendations in a computing environment in accordance with an embodiment of the present disclosure. FIG. 3 will be explained in conjunction with the description of FIG. 1 and FIG. 2.

Specifically, FIG. 3 illustrates a sequential flow diagram for intent-based factorization and computational simulation, in accordance with the embodiments presented herein.

At step 302, the controller 114 forming a part of the server computer 106 may receive a user input for executing one or more intended tasks from a user in accordance with step 202. For instance, a user may provide the user input in a text, image, video, gesture, or audio format. The user input may reach the controller via the network 102 or locally. The user input associated with an intent of a user may be received in the form of multiple input streams, as will be described further with reference to FIG. 4. The user input may be processed by the controller 114, including or in conjunction with, the system units discussed above.

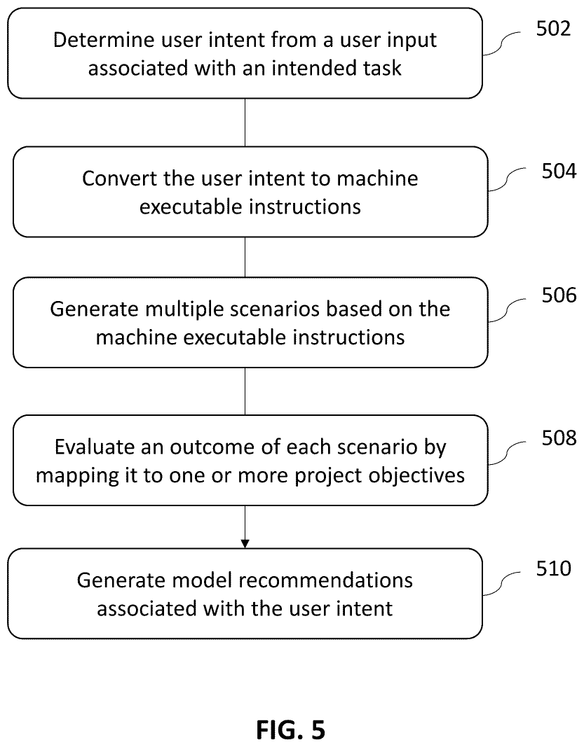

At step 304, the controller 114 may determine an intent of the user based on parsing the user input as provided for the performance of the task which may be the constructional project. Specifically, the controller 114 may employ techniques, such as, machine learning and/or AI computation, for processing user input based on ecosystem influencers. The user input may be in the form of machine executable instructions. Further, the machine executable instructions may be further processed in view of ecosystem influencers to determine an intent of the user. Further details of the processing will be described with reference to FIG. 4-5.

Thereafter, the intent as determined may be computed as a feature set or feature vector for processing by a machine learning model in accordance with step 204 communicated to model ensemble 112. The feature set may be a vector containing multiple elements about an object, such as, a user intent. Putting feature sets or vectors for objects together can make up a feature space. The granularity depends on what someone is trying to learn or represent about the object. In an example, a 3-dimensional feature may be enough for simulating a passage in a building as compared to a plinth beam which may require 5 dimensional features for being more sensitive structural component of a building. In an embodiment, for a multi-dimensional design project, a feature set may include one or more of a position coordinate system, cost, sustainability, safety, facility management, a construction principle, and an industry standard.

In step 306, the model ensemble 112 defining an ensemble learning may process one or more data feeds received from the knowledge database 132 based on the user intent determined by the controller 114 in accordance with step 206. Thereafter, the model ensemble 112 communicates the result, such as the generated model recommendation(s), back to the controller 114.

In step 308, the controller 114 selects at-least one plan of action for executing the at least one task based on processing the data feed and determined intent. Further, in an embodiment, the controller 114 executes one or more selected plan of actions in the virtual environment based on the processed data feeds. The notifier 116 facilitates such operation by simulating the plan of action for performance of the intended task as either virtual reality or augmented reality. The present step 308 corresponds to the step 208 of FIG. 2.

FIG. 4 is a schematic diagram illustrating a system for processing multiple input streams to determine an intent of a user, in accordance with an embodiment of the present disclosure. An input, associated with an intent of a user, may be received in the form of, some or all of, an acoustic input 402, an image input 404, a gesture input 406, and a text input 408. For example, a user may provide a multimedia input in the form of a reference image of a building, along with a textual input providing details about the building, followed by an acoustic query related to the user intent asking the system to create a construction plan for a similar building. Thus, in this example, user input is received in the form of a first input stream, through the image input 404, a second input stream, through the text input 408, and a third input stream, through the acoustic input 402.

Further, as shown in FIG. 4, user input from all non-textual input streams, such as acoustic input 402, image input 404, and gesture input 406, is converted to a textual format. That is, user input from acoustic input 402 is converted to a textual format at Acoustic to textual converter 410, user input from image input 404 is converted to a textual format at Image to textual converter 412, and user input from gesture input 406 is converted to a textual format at Gesture to textual converter 414. Any known techniques of converting a non-textual data to text may be used, such as, but not limited to, Markov Models, Deep Neural Networks (DNNs), Convolutional Neural Network (CNNs), and the like, may be applied by the converters described above.

Textual data from Acoustic to textual converter 410, Image to textual converter 412, Gesture to textual converter 414, and text input 408 is received by Intent-based processing units 416, 418, 420, 422, respectively. Intent-based processing units 416, 418, 420, 422 decompose the received textual data into smaller units of data, such as, intent-based data sub-units, for processing an intent of the user. In an embodiment, the Intent-based processing units may apply any known parsing techniques to identify keywords and phrases that may be relevant to identify an explicit or implicit intent of the user. In an example, the Intent-based processing units may parse and decompose the textual data into smaller units of data using a Machine Learning (ML) enabled parser that intuitively and predictively executes the parsing and/or keyword extraction process. In yet another example, non-ML enabled parser may be employed that may be based on linear regression, Markov Model etc. For example, a speech-to-text converted input data may refer to a query by the user regarding a status of a consignment X from a supplier Y. In this scenario, the Intent-based processing unit 416 parses and decomposes the query into smaller, relevant units, such as, “status”, “consignment X”, and “supplier Y”. These smaller units of data may be relevant in determining the intent of the user query.

Further, the Intent-based processing units 416, 418, 420, 422 may provide the decomposed smaller units of data to Machine executable instructions units 424, 426, 428, and 430, respectively. Machine executable instructions units 424, 426, 428, and 430 may convert the data received from the Intent-based processing units 416, 418, 420, 422 into machine language instructions that may be fed to a machine or a process, such as an Artificial Intelligence (AI) model, for further processing. It should be noted that any known techniques of converting data into machine executable instructions may be employed by the Machine executable instructions units 424, 426, 428, and 430. Further, the system may include a combinatorial module 432 that combines processed data, in the form of machine executable instructions, for example, from one or more of the Machine executable instructions units 424, 426, 428, and 430 into a combined machine executable instructions data. Thus, user input from multiple input streams may be processed and combined into a final, combined machine executable instructions data. The machine executable instructions data may further be processed, by means of AI models, for example, in view of an ecosystem and/or contextual data to determine an intent of the user, as will be described in detail below.

FIG. 5 illustrates a method for generating model recommendations in a computing environment in accordance with an embodiment of the present disclosure. FIG. 5 will be explained in conjunction with the description of FIG. 1-FIG. 4.

Specifically, FIG. 5 illustrates a sequential flow diagram for analysis of user input to generate model recommendations, in accordance with the embodiments presented herein.

At step 502, a user intent is determined from a user input received for executing one or more intended tasks from a user in accordance with step 202. As described above with reference to FIG. 4, a user input associated with an intent of a user may be received in the form of a single media input or a multimedia input. The received user input may be converted to machine executable instructions. Further, in an embodiment, the machine executable instructions may be analyzed based on ecosystem influencers. The term “ecosystem influencers” as used herein may refer to influencers, constraints, and factors that define a context for interpreting the user input and determining an intent of the user. In an embodiment, the ecosystem influencers may include factors, such as a project phase, supply constraints, quality impact and the like. For example, the user may provide an input, such as, “What is the health of the project?” The user input is analyzed based on ecosystem influencers associated with the project. The ecosystem influencers may indicate that the project is near completion, and hence, the term “health” in user query and/or input may be interpreted as a completion status and/or timeline for the project. Thus, the system may intelligently rule out other metrices associated with the project and provide contextually relevant data to the user. In some embodiments, the ecosystem influencers may also include other factors, such as, user preferences, historical data, race and/or ethnicity of the user, geolocation factors, and the like.

Further, in an embodiment, the machine executable instructions may further be analyzed based on one or more project objectives associated with the project. The term project objectives, as used herein, may refer to an intent, a goal, or an objective that should be met, to an extent, while executing a task, a project, or an activity. These may include, but are not limited to, a time objective (e.g., a timeline for a project), a cost objective (e.g., a budget for a project), a quality objective (e.g., a quality standard for a project), a sustainability objective (e.g., minimizing CO2 emissions and other emissions that may result in global warming for a project), an efficiency objective (e.g., a supplier and/or factory efficiency target for a project), and a health objective (e.g., the use of non-toxic materials for a manufacturing project) associated with the project. For example, the project objective for a construction of a building may include a timeline goal (in an example, say, of six months). In another example, the project objective for a project for manufacturing window panes for a building may be a sustainability based objective, such as, minimizing carbon emissions. In this case, the project objective may correspond to a sustainability metrics, such as, clean energy usage, carbon footprint, etc. In another embodiment, the project objective may be a combination of multiple objectives, such as, a budget goal in association with a timeline for completing the project. In this case, both the budget and the timeline goals may be considered as the project objectives. Thus, at step 502, a user intent may be determined based on the analysis of the received user input, as discussed above.

At step 504, the user intent determined at step 502, is converted to machine executable instructions for further processing. In an embodiment, the processing may be performed using machine learning techniques and/or through one or more AI models.

At step 506, multiple scenarios are generated based on the machine executable instructions. The term “scenarios” as used herein, may refer, but is not limited to, plans or layouts or schemes for processing of a task or a sub-task that may vary or differ in at least one aspect. For example, the scenarios may vary in the order of execution of tasks or sub-tasks, an outcome associated with the scenarios, input data, output data, execution algorithms, or a combination of the above.

In an embodiment, the scenarios may be generated by modifying one or more parameters associated with a task. For example, a user intent may indicate that a user, associated with a construction project, intends to complete the project by a certain date. The user intent may then be converted into instructions in a machine language for further processing by the system using ML techniques, AI algorithms and/or deep learning techniques. The processing may include determining one or more parameters associated with the project and/or the user intent. For example, the parameters associated with the construction project may include supply chain constraints, manufacturing processes, factory schedules, logistical constraints, standard regulations, and the like. The system may intelligently vary one or more of these parameters to generate multiple scenarios. For example, the system may determine that in order to complete the construction project by the date indicated in the user intent, the raw materials must be procured a week earlier, and a first scenario may be generated accordingly. Further, it may be determined that modifying the manufacturing process or altering the factory schedule would also result in competing the project within the intended timeline, and hence, a second scenario may be generated. Thus, the system may intelligently process several variations and combinations of the determined parameters associated with a project or a task, and may generated multiple scenarios.

At step 508, an outcome of each scenario is evaluated by mapping it to one or more project objectives. The term project objectives, as used herein, may refer to an intent, a goal, or an objective that should be met, to an extent, while executing a task, a project, or an activity. These may include, but are not limited to, a time objective (e.g., a timeline for a project), a cost objective (e.g., a budget for a project), a quality objective (e.g., a quality standard for a project), a sustainability objective (e.g., minimizing CO2 emissions and other emissions that may result in global warming for a project), an efficiency objective (e.g., a supplier and/or factory efficiency target for a project), and a health objective (e.g., the use of non-toxic materials for a manufacturing project) associated with the project. For example, the project objective for a construction of a building may include a timeline goal (in an example, say, of six months). In another example, the project objective for a project for manufacturing window panes for a building may be a sustainability based objective, such as, minimizing carbon emissions. In this case, the project objective may correspond to a sustainability metrics, such as, clean energy usage, carbon footprint, etc. In another embodiment, the project objective may be a combination of multiple objectives, such as, a budget goal in association with a timeline for completing the project. In this case, both the budget and the timeline goals may be considered as the project objectives.

Thus, at step 508, an outcome associated with each scenario is evaluated based on the project objectives associated with the project. The term “outcome”, as used herein, may refer to a result, an output, or an impact of a scenario. In an embodiment, the outcome of each scenario relates to an impact of the scenario on the project objectives. For example, if the project objective for a project includes a budget goal, then an associated cost impact for each of the scenarios may be evaluated by the system. One of the scenarios may include procuring raw material at a higher cost to achieve project completion timeline intended by the user, however, the increased cost of procurement may not align with the budget goal set in the project objectives. Thus, the outcome of this scenario may not be in alignment with the project objectives and therefore, the scenario may be discarded from further processing. That is, in an embodiment, the evaluation of the scenarios may include generating a set of constraints based on one or more project objectives. In the example discussed above, project budget may be identified as a constraint. Further, the outcome of each of the plurality of scenarios may be mapped to the set of constraints, and one or more of the plurality of scenarios may be shortlisted based on the mapping of the outcome to the project objectives.

At step 510, model recommendation(s) associated with the user intent are generated based on the evaluation performed at step 508. Model recommendation may refer to an optimized model that may be generated by the system based on the evaluation of the scenarios. Optimized model may refer to a model or an execution plan, that outlines the optimum or the most efficient way of executing a task or achieving a desired result. In an embodiment, ML techniques, AI algorithms and/or deep learning techniques may be employed for generating the optimized model. Some of the deep learning techniques and AI algorithms to generate the optimized model may include, among others (but not limited to), node2vec techniques for prediction, Greedy Algorithm, Dijkstra's algorithm, and Profit Maximization algorithms. The generated optimized model(s) may be presented to a user, or a machine for further processing, in the form of the model recommendation(s). Thus, the model recommendation associated with the user intent may outline a plan of execution, or a set of instructions for the user to execute the intended task within the constraints of project objectives and/or ecosystem influencers. Further, in an embodiment, the model recommendation(s) may be presented to the user through a visual display. Additionally, the system may enable the user to execute a modification to the model recommendation(s) in real-time through an interface.

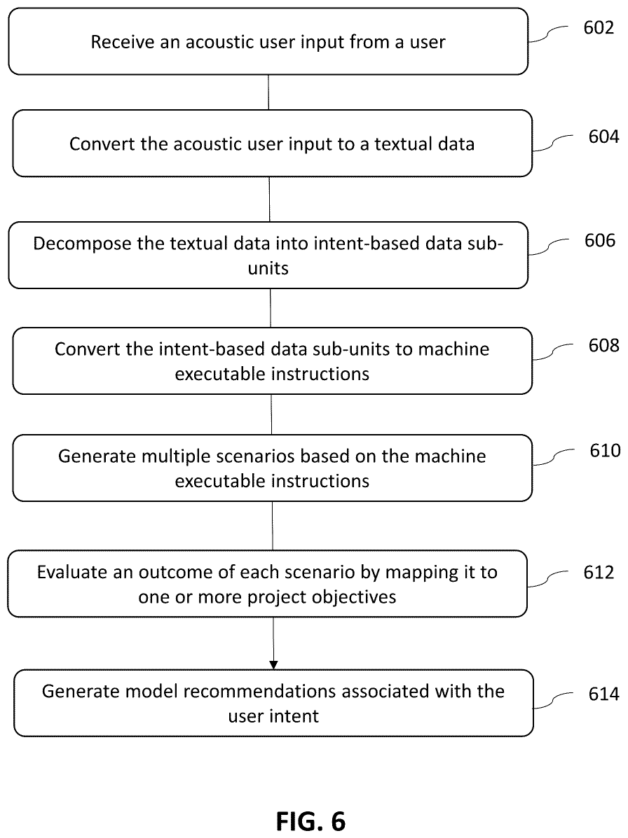

FIG. 6 illustrates a method for generating model recommendations based on a user input in a computing environment in accordance with an embodiment of the present disclosure. FIG. 6 will be explained in conjunction with the description of FIG. 1-FIG. 5.

Specifically, FIG. 6 illustrates a sequential flow diagram for generating model recommendations based on an acoustic user input, in accordance with the embodiments presented herein.

At step 602, an acoustic user input is received from a user. As described above, with reference to FIG. 4, a user input may be received through different input streams, for example, as an acoustic input 402.

At step 604, the acoustic input 402 is converted to a textual format, for example, at Acoustic to textual converter 410, as discussed above with reference to FIG. 4.

At step 606, the textual data is decomposed into intent-based data sub-units. As discussed above, the Intent-based processing unit 416 may decompose the textual data into smaller units of data, such as, intent-based data sub-units, for further processing. The Intent-based processing units may apply any known parsing techniques to identify keywords and phrases that may be relevant to identify an explicit or implicit intent of the user.

At step 608, the intent-based data sub-units are converted into machine executable instructions. In an embodiment, the Intent-based processing units 416 may provide the decomposed smaller units of data to Machine executable instructions unit 424. Machine executable instructions unit 424 may convert the data received from the Intent-based processing unit 416 into machine language instructions that may be fed to a machine or a process, such as an Artificial Intelligence (AI) model, for further processing.

At step 610, multiple scenarios may be generated based on the machine executable instructions. The scenarios may be generated as discussed above in step 506 with reference to FIG. 5.

At step 612, an outcome of each scenario may be evaluated by mapping it to one or more projectives, as discussed above in step 508 with reference to FIG. 5.

At step 614, model recommendations associated with the user intent may be generated, as discussed above in step 510 with reference to FIG. 5

In an embodiment, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., be non-transitory. Examples include random access memory (RAM), read-only memory (ROM), volatile memory, nonvolatile memory, hard drives, CD ROMs, DVDs, flash drives, disks, and any other known physical storage media.

The terms “comprising,” “including,” and “having,” as used in the claim and specification herein, shall be considered as indicating an open group that may include other elements not specified. The terms “a,” “an,” and the singular forms of words shall be taken to include the plural form of the same words, such that the terms mean that one or more of something is provided. The term “one” or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition, or step being referred to is an optional (not required) feature of the disclosure.

The disclosure has been described with reference to various specific and preferred embodiments and techniques. However, it should be understood that many variations and modifications may be made while remaining within the spirit and scope of the disclosure. It will be apparent to one of ordinary skill in the art that methods, devices, device elements, materials, procedures, and techniques other than those specifically described herein can be applied to the practice of the disclosure as broadly disclosed herein without resort to undue experimentation. All art-known functional equivalents of methods, devices, device elements, materials, procedures, and techniques described herein are intended to be encompassed by this disclosure. Whenever a range is disclosed, all subranges and individual values are intended to be encompassed. This disclosure is not to be limited by the embodiments disclosed, including any shown in the drawings or exemplified in the specification, which are given by way of example and not of limitation. Additionally, it should be understood that the various embodiments of the networks, devices, and/or modules described herein contain optional features that can be individually or together applied to any other embodiment shown or contemplated here to be mixed and matched with the features of such networks, devices, and/or modules.

While the disclosure has been described with respect to a limited number of embodiments, those skilled in the art, having benefit of this disclosure, will appreciate that other embodiments can be devised which do not depart from the scope of the disclosure as disclosed herein.

We claim:

1. A method for generating a model recommendation in a computing environment, the method comprising:
determining a user intent based on a user input for executing at least one intended task by a user;
converting the determined user intent to one or more machine executable instructions;
generating a plurality of scenarios based on the one or more machine executable instructions;
evaluating an outcome of each of the plurality of scenarios by mapping it to one or more project objectives associated with the at least one intended task; and
generating at least one model recommendation associated with the user intent based on the evaluation.

2. The method of claim 1, further comprising generating the plurality of scenarios comprises modification of one or more parameters associated with the at least one intended task, each modification associated with a corresponding outcome.

3. The method of claim 1, further comprising:
receiving the user input through a plurality of input streams, at least one of the plurality of input streams corresponding to a non-textual format;
processing the plurality of input streams including converting the non-textual format of the at least one of the plurality of input streams to a textual format;
generating one or more intent-based data sub-units by parsing and processing each of the plurality of input streams;
generating machine executable instructions corresponding to the one or more intent-based data sub-units; and
combining the generated machine executable instructions corresponding to each of the plurality of processed input streams to a combined machine executable instruction.

4. The method of claim 1, further comprising:
generating one or more intent-based data sub-units by parsing and processing the received user input; and
converting the one or more intent-based data sub-units to machine executable instructions.

5. The method of claim 1, further comprising receiving the user input as at least one of a text, image, video, gesture, and audio format.

6. The method of claim 1, further comprising determining the user intent corresponding to a plurality of preferences of the user pertaining to execution of the at least one intended task.

7. The method of claim 1, further comprising classifying the user intent as at least one of a temporal intent, a spatial intent, a fiscal intent, and a societal intent.

8. The method of claim 1, further comprising evaluating the outcome of each of the plurality of scenarios, the evaluating comprises:
generating a set of constraints based on the one or more project objectives;
mapping the outcome of each of the plurality of scenarios to the set of constraints; and
shortlisting one or more of the plurality of scenarios based on the mapping.

9. The method of claim 1, further comprising:
providing the at least one model recommendation to the user through a visual display; and
enabling the user to execute a modification in real-time through an interface to the at least one model recommendation.

10. A system for generating a model recommendation in a computing environment, said system comprising a controller configured to:
determine a user intent based on a user input for executing at least one intended task by a user;
convert the determined user intent to one or more machine executable instructions;
generate a plurality of scenarios based on the one or more machine executable instructions;
evaluate an outcome of each of the plurality of scenarios by mapping it to one or more project objectives associated with the at least one intended task; and
generate at least one model recommendation associated with the user intent based on the evaluation.

11. The system of claim 10, the controller is further configured to:
generate the plurality of scenarios by modifying one or more parameters associated with the at least one intended task, each modification associated with a corresponding outcome.

12. The system of claim 10, the controller is further configured to:
receive the user input through a plurality of input streams, at least one of the plurality of input streams corresponding to a non-textual format;
process the plurality of input streams including converting the non-textual format of the at least one of the plurality of input streams to a textual format;
generate one or more intent-based data sub-units by parsing and processing each of the plurality of input streams;
generate machine executable instructions corresponding to the one or more intent-based data sub-units; and
combine the generated machine executable instructions corresponding to each of the plurality of processed input streams to a combined machine executable instruction.

13. The system of claim 10, the controller is further configured to:
generate one or more intent-based data sub-units by parsing and processing the received user input; and
convert the one or more intent-based data sub-units to machine executable instructions.

14. The system of claim 10, wherein the user input is in at least one of a text, image, video, gesture, and audio format.

15. The system of claim 10, wherein the determined user intent is classifiable as at least one of a temporal intent, a spatial intent, a fiscal intent, and a societal intent.

16. The system of claim 10, the controller is further configured to:
generate a set of constraints based on the one or more project objectives;
map the outcome of each of the plurality of scenarios to the set of constraints; and
shortlist one or more of the plurality of scenarios based on the mapping.

17. The system of claim 10, the controller is further configured to:
provide the at least one model recommendation to the user through a visual display; and
enable the user to execute a modification in real-time through an interface to the at least one model recommendation.

18. A non-transitory computer-readable storage medium, having stored thereon a computer-executable program which, when executed by at least one processor, causes the at least one processor to:
determine a user intent based on a user input for executing at least one intended task by a user;
convert the determined user intent to one or more machine executable instructions;
generate a plurality of scenarios based on the one or more machine executable instructions;
evaluate an outcome of each of the plurality of scenarios by mapping it to one or more project objectives associated with the at least one intended task; and
generate at least one model recommendation associated with the user intent based on the evaluation.

19. The non-transitory computer-readable storage medium of claim 18, the computer-executable program further causes the at least one processor to:
receive the user input through a plurality of input streams, at least one of the plurality of input streams corresponding to a non-textual format;
process the plurality of input streams including converting the non-textual format of the at least one of the plurality of input streams to a textual format;
generate one or more intent-based data sub-units by parsing and processing each of the plurality of input streams;
generate machine executable instructions corresponding to the one or more intent-based data sub-units; and
combine the generated machine executable instructions corresponding to each of the plurality of processed input streams to a combined machine executable instruction.

20. The non-transitory computer-readable storage medium of claim 18, the computer-executable program further causes the at least one processor to:
provide the at least one model recommendation to the user through a visual display; and
enable the user to execute a modification in real-time through an interface to the at least one model recommendation.
